(19) United States
(12) Patent Application Publication
(10) Pub. No.: US 2025/0249674 A1
(43) Pub. Date: Aug. 7, 2025

(54) METHOD AND PREPARATION UNIT

(71) Applicant: DISCO HI-TEC EUROPE GmbH, Munich (DE)

(72) Inventor: De Ming CHONG, Munich (DE)

(21) Appl. No.: 19/046,057

(22) Filed: Feb. 5, 2025

(30) Foreign Application Priority Data
Feb. 7, 2024 (DE) 10 2024 201 087.1

(51) Int. Cl. B32B 37/06; B32B 27/08; B32B 27/32; B32B 27/36; B32B 37/04; B32B 37/10; B32B 37/18; B32B 41/00; H01L 21/67

(52) U.S. Cl. CPC B32B 37/06; B32B 27/08; B32B 27/32; B32B 27/36; B32B 37/04; B32B 37/1018; B32B 37/182; B32B 41/00; H01L 21/67132; B32B 2307/308; B32B 2323/10; B32B 2367/00; B32B 2457/14

(57) ABSTRACT

A method of preparing a workpiece for processing is provided, wherein the method comprises the steps of providing the workpiece, providing a protective sheeting comprising at least a first layer and a second layer, wherein the second layer is formed of a material having a higher glass-transition temperature or melting temperature than the first layer, combining a first side of the workpiece and the first layer of the protective sheeting, and applying heat to the first layer of the protective sheeting through the second layer thereof. Further, a preparation unit for preparing a workpiece is provided that is configured to perform this method.

### TECHNICAL FIELD

The present disclosure relates to a method of preparing a workpiece for processing and to a preparation unit for preparing a workpiece for processing.

### BACKGROUND

Device chips are generally fabricated by forming devices on a front side of a substrate (wafer) in regions that are defined by division lines. However, the devices formed on the front side of the substrate cause the front side to have an uneven profile. In other words, the front side is not flat but has various grooves, depressions and protrusions resulting in the surface of this side having an uneven profile and may result in difficulties when processing the substrate.

More specifically, this unevenness of the front side of the substrate has shown to be susceptible to damage or has led to damage when being mechanically processed such as by grinding or dicing from the side of the substrate opposite to the front side. One of the reasons identified to be responsible is that the force applied during processing is unevenly distributed over the surface of the front side of the substrate due to varying support, which in turn tends to cause stress peaks, which may lead to cracks occurring in the substrate and the devices.

As an approach to prevent this damage during processing, different techniques have been proposed to compensate for the uneven surface of the substrate's front side that causes the uneven support.

For example, US 2017/062278 A1 proposes attaching a protective film to one side of a wafer for covering devices on the wafer, wherein the protective film is adhered to at least a part of the one side of the wafer with an adhesive, and providing a carrier having a curable resin applied to a front surface thereof. The method further comprises attaching the one side of the wafer, having the protective film attached thereto, to a front surface of a carrier, so that the protrusions protruding from the plane surface of the wafer are embedded in the curable resin.

Another technique that has been proposed (see for example JP 2013-021017 A) is the application of a tape to the front side of a substrate with devices formed thereon. After application of the tape to this uneven device surface on the substrate, the tape is subject to surface variations on its exposed surface. These are then removed by planarizing the exposed surface via a kind of milling process using a diamond bit. Also, this process takes additional time and rather complex machinery for being properly performed.

Further, US 2020/335 382 A1 proposes stacking a sheet and a flat plate on a front side of a substrate. This procedure is followed by a thermocompression bonding step. During the application of a compression force to the sheet on the substrate via a flat plate, the sheet is heated via the substrate. Thus, planarization is performed by heating the sheet from one side and applying an external force to the sheet via the flat plate from the opposite side. Afterwards, the flat plate is removed. However, this technique has basically turned out to be effective in cases of a comparatively small unevenness of the surface profile.

### SUMMARY OF THE INVENTION

Consequently, there remains a need for simplified and enhanced methods to planarize an uneven surface of a workpiece, wherein the uneven surface is particularly caused by devices formed on a front side of a substrate or wafer.

To address this objective, the present disclosure provides a method of preparing a workpiece for subsequent processing. The method comprises providing the workpiece and a protective sheeting including at least a first layer and a second layer. The second layer is formed of a material having a higher glass-transition temperature and/or melting temperature than the first layer. The method also comprises a step of combining a first side of the workpiece and the first layer of the protective sheeting and applying heat to the first layer of the protective sheeting through the second layer thereof.

This method has the advantage that it allows for essentially evening out an unevenness present on the first side of the workpiece that is, for example, caused by devices arranged on that side.

Evening particularly achieved via the out is protective sheeting by embedding the uneven surface of the first side of the workpiece in the first layer of the protective sheeting while the second layer is for providing an essentially planar surface that may be used to support the workpiece, in particular during mechanical processing with processing forces applied to the workpiece.

Also, applying heat to the first layer via the second layer enables a uniform thermally conductive path independent of the material and thickness of the workpiece. It allows for a fast and responsive heating procedure of the first layer.

At least when applying heat to the first layer of the protective sheeting, the first side of the workpiece preferably faces a heating means. In this manner, a uniform heating over the first side of the workpiece may be achieved that positively affects the levelling function of the protective sheeting.

The difference in glass transition temperature and/or melting temperature of the first and second layers allows for controlling the malleability of the two layers. Particularly, it allows to heat the first layer to be more malleable than the second layer. More preferably, it allows to control the temperature of the two layers so that the material of the first layer becomes soft enough to absorb the unevenness on the first side of the workpiece. For example, the material of the first layer may plastically deform by material located at a protrusion on the first side being displaced to an adjacent less protruded region. At the same time, the second layer may essentially maintain a more solid state that substantially prevents deformation.

The first layer of the protective sheeting is preferably in contact with the first side of the workpiece. This contact of the first layer with the first side of the workpiece (i.e., in touch or without anything else in between) is advantageous for the first layer in compensating unevenness of the first side of the workpiece.

The method may further comprise arranging the second layer of the protective sheeting on the heating means, wherein the heating means is configured to apply heat to the first layer of the protective sheeting through the second layer thereof.

Accordingly, the heating means is arranged to apply heat to the first layer via the second layer in a controlled environment so that it is possible to simply use a predetermined heating protocol. In other words, heat may be applied to the first layer in a predeterminable manner.

The second layer is preferably in contact with the heating means. Further, the second layer of the protective sheeting may be held on the heating means under suction.

If the second layer is arranged in contact with the heating means, an efficient and uniform heat transfer may be achieved. This may further be supported by an enhanced contact between the heating means and the second layer using suction.

The first layer and/or the second layer are preferably provided as a foil or film. This enhances adaptivity to the surface of the workpiece during application and allows for an easy removal after processing.

The first layer and the second layer are preferably formed of a polymer material (in particular polymer film(s)), wherein the polymer materials of the first and second layer are even more preferably different from each other. For example, the first layer may be formed of polyolefin or polypropylene and/or the second layer may be formed of polyethylene terephthalate (PET).

Polymer materials are easy to handle and may easily be provided as a film. Using different polymer materials for the first and second layers allows for adapting the materials or material properties according to their function for the protective sheeting.

As previously indicated, surface structures may be formed or present on the first side of the workpiece. When applying heat to the first layer of the protective sheeting, the first layer is softened, such that, after applying heat to the first layer of the protective sheeting, the surface structures are embedded in the first layer. When applying heat to the protective sheeting, preferably only the first is layer softened. In other words, the first layer preferably softens (e.g. by assuming a malleable state) while the second layer remains in an undeformed, unsoftened or solid state.

The first layer of the protective sheeting is preferably heated to a temperature above the glass-transition temperature or melting temperature of the first layer but below the glass-transition temperature or melting temperature of the second layer.

Accordingly, the first layer becomes malleable before the second layer, which enhances its embedding properties. The second layer may, in contrast, keep an even surface, which is, as discussed above, advantageous for the support of the workpiece during processing. This is particularly achieved if the second layer is only heated below its glass transition temperature or melting temperature.

At least the step of arranging a first side of the workpiece on the first layer of the protective sheeting and/or applying heat to the first layer of the protective sheeting may essentially be performed under vacuum condition, preferably inside a vacuum chamber.

Using a vacuum environment during the process of mounting the first layer to the workpiece particularly prevents gas from getting trapped in between the workpiece and the first layer, which may otherwise form bubbles. It may also speed up the process of arranging, applying, or embedding the first layer since there is no gas hindering the first layer and the workpiece from getting into contact.

At least while or after applying heat to the first layer of the protective sheeting through the second layer thereof, the workpiece and the protective sheeting may be pressed against each other, preferably by applying a pressure load via the workpiece and/or the second layer of the protective sheeting.

This enhances and accelerates the embedding process of the first layer, in particular in combination with a vacuum environment. In this process, particularly a displacement of material of the first layer into depressions and around protrusions is supported by mechanical pressure.

This pressure may be applied via the workpiece and/or the second layer, i.e., the means to apply pressure is arranged on that side or these sides. In each case, the pressure is applied so that it acts on the first layer and enhances the process of the first layer embedding the depressions and protrusions of the side of the workpiece facing the first layer. Applying the pressure via the workpiece while the protective sheeting is held on a chuck table is preferred due to easier handling.

The second layer, in particular the side of the second layer opposite to the side facing the first layer, may comprise a substantially flat shape, wherein the shape of the second layer essentially remains unchanged when applying heat to the first layer of the protective sheeting.

Before the step of applying heat to the first layer, the side of the second layer of the protective sheeting facing away from the workpiece preferably has an even or flat surface when being placed on a flat surface, e.g., the surface of a chuck table or pad. Even more preferably, this also applies to the side of the first layer facing the workpiece. This condition of the second layer's side(s) particularly also remains essentially unchanged upon the step of applying heat (and possibly pressure), wherein the side of the first layer facing the workpiece at least partly embeds the surface topography of the side of the workpiece facing the first layer.

As a result, the flat side of the second layer of the for protective sheeting provides a flat support surface f processing the workpiece, wherein the deformed first layer allows to keep an even support on the side of the workpiece. As a result, cracks that may otherwise occur upon processing may be prevented.

The present disclosure also addresses above-noted objective by providing a preparation unit for preparing a workpiece, the preparation unit being configured for attaching a protective sheeting to the workpiece. The protective sheeting comprises at least a first layer to be arranged on the workpiece side and a second layer to be arranged on the side opposite to the workpiece side. The workpiece preparation unit comprises a chuck table including a holding surface for holding the workpiece via the second layer, a heating means, and a control unit configured to control the heating means so that the first layer is heated via the second layer according to a predetermined heating protocol.

Accordingly, the preparation unit is configured to apply any of the methods described above to a protective sheeting for mounting the protective sheeting to a workpiece.

Preferably, the predetermined heating protocol heats the first layer of the protective sheeting via the second layer of the protective sheeting so that the first layer softens (i.e., it becomes malleable) and is able to embed the surface structure of the workpiece facing the first layer.

Thus, the preparation unit achieves above-described advantages for achieving an even support of the workpiece during subsequent machining (e.g., grinding, dicing, etc.).

The preparation unit particularly comprises a pressure application means arranged for applying a pressure load to the first layer.

As described above, applying pressure supports the embedding process of the workpiece's surface structures into the first layer. The pressure application means preferably has a generally flat surface to apply pressure via the workpiece side and/or the second layer side to act between the workpiece and the first layer during the embedding process. In other words, the pressure application means is particularly arranged on either or both sides of pressure application.

Further, the preparation unit may comprise a camera arranged for inspecting an exposed surface of the second layer of the protective sheeting attached to the workpiece.

Such a camera allows to inspect the surface structure of workpiece through the protective sheeting and may also be used to check the result of preparing the workpiece for further processing. It may particularly investigate the embedding of the surface structure and/or the flatness of the exposed side of the second layer.

Further, the camera may be configured as a means to control machining. For example, the camera may be used to adjust the position of a dicing blade or a laser beam for processing the workpiece.

### SHORT DESCRIPTION OF THE DRAWINGS

The following figures schematically illustrate exemplary embodiments of a method of preparing a workpiece for processing according to the present disclosure as well as parts of a preparing unit for preparing a workpiece for processing. In these figures, same reference signs refer to features throughout the drawings that have the same or an equivalent function and/or structure. It is to be understood that the figures illustrate schematic examples of how the method of preparing a workpiece for processing is performed in accordance with the present disclosure but without limiting the invention thereto.

FIG. 1 schematically illustrates an exemplary embodiment and arrangement of a workpiece and a protective sheeting used for preparing the workpiece for subsequent processing;

FIG. 2 schematically illustrates the arrangement shown in FIG. 1 placed in a preparation unit for preparing the workpiece;

FIG. 3 schematically illustrates an exemplary embodiment of a process of preparing the workpiece;

FIG. 4 schematically illustrates another embodiment of the process of preparing the workpiece for subsequent processing;

FIG. 5 schematically illustrates an inspection of the workpiece prepared in accordance with the present disclosure;

FIG. 6 schematically illustrates an example of subsequent processing of a workpiece that has been prepared in accordance with the present disclosure; and

FIG. 7 schematically illustrates a workpiece formed as a wafer.

### DETAILED DESCRIPTION OF PREFERRED EMBODIMENTS

The method of preparing a workpiece for processing and the preparation unit for preparing a workpiece for processing according to the present disclosure are further described in more detail below with reference to the accompanying figures.

In this respect, it should be noted that the figures are schematically illustrating various configurations of the method and parts of the preparation unit and that the dimensions of the sheetings, workpieces, machine parts are exaggerated (i.e., shown bigger or smaller) for explanatory purposes.

As discussed above, the present disclosure has the objective to prevent a workpiece to be damaged when the workpiece is processed, in particular by mechanical processing such as grinding, dicing, and the like. During processing, forces are applied or generated that cause stresses within the workpiece. If these stresses exceed a limit of a material of the workpiece, the stresses may be released by cracks occurring. It is also possible that distortions of the material or residual stresses are caused by such processing.

One factor that has a significant influence and may prevent these adverse effects is a proper support of the workpiece during machining. On the one hand, this support is provided by the support means of the machine processing the workpiece. However, on the other hand it also depends on the characteristics of the workpiece.

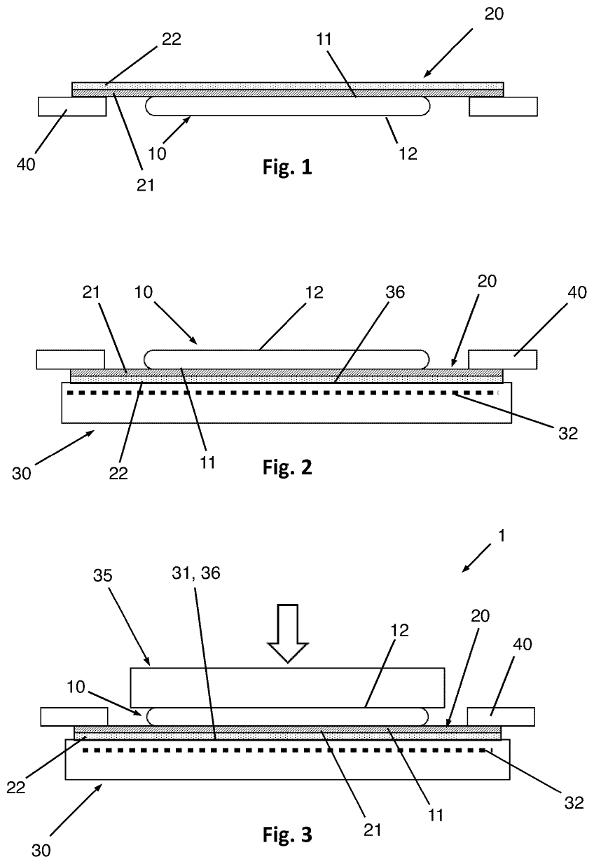

As illustrated in FIG. 1, the workpiece 10 to be supported on a workpiece support 30 may, for example, be a wafer or an ingot. The workpiece 10 comprises a substrate that may be any (semiconductor) substrate.

The substrate may, for example, comprise a semiconductor, glass, sapphire (Al2O3), ceramic, such as an alumina ceramic, quartz, zirconia, PZT (lead zirconate titanate), polycarbonate, optical crystal material or the like. In particular, the substrate may comprise silicon carbide (Sic), silicon (Si), gallium arsenide (GaAs), gallium nitride (GaN), gallium phosphide (GaP), indium arsenide (InAs), indium phosphide (InP), silicon nitride (SiN), lithium tantalate (LT), lithium niobate (LN), aluminium nitride (AlN), silicon oxide (SiO₂) or the like.

The substrate may be a single crystal substrate, a glass substrate, a compound substrate, such as a compound semiconductor substrate, e.g., a SiC, SiN, GaN or GaAs substrate, or a polycrystalline substrate, such as a ceramic substrate.

As noted above, the substrate may be a wafer. For example, the substrate may be a semiconductor-sized wafer. Herein, the term “semiconductor-sized wafer” refers to a wafer with predetermined dimensions (standardized dimensions), in particular, the diameter (i.e., standardized diameter, outer diameter) of a semiconductor wafer. Such dimensions of semiconductor wafers are, for example, defined in the SEMI standards. For example, the dimensions of polished single crystal silicon wafers are defined in the SEMI standards M1 and M76. The semiconductor-sized wafer may be a 3 inch, 4 inch, 5 inch, 6 inch, 8 inch, 12 inch, or 18 inch wafer.

The substrate is made of a single material or of a combination of different materials, e.g., two or more of the above-identified materials.

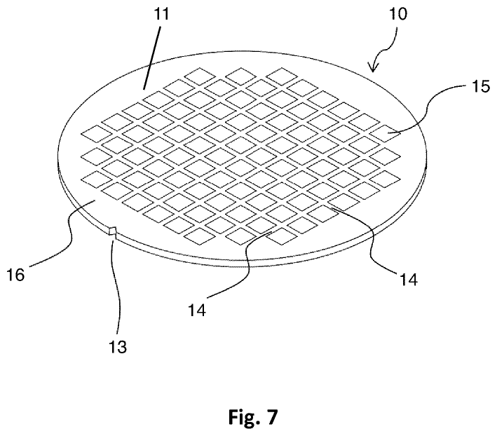

On the substrate, in particular a wafer, functional layers or devices may be formed (see FIG. 7). Such functional layers or devices are preferably formed on one side of the substrate. On this side, the substrate may comprise a central device area 15, in which devices or functional layers are formed, and a peripheral marginal area 16 surrounding said device area 15. In said peripheral marginal area 16, preferably no devices or functional layers are formed.

In the following, the side of the substrate or workpiece 10 having the device area 15 formed thereon will generally be referred to as the first or front side 11 of the workpiece 10. The opposite side of the substrate or workpiece 10 will be referred to as the second or back side 12 of the workpiece 10.

The devices in the device area 15 may be ICs (integrated circuits) and LSIs (large scale integrations). For example, the devices may be semiconductor devices, power devices, optical devices, medical devices, electrical components, MEMS devices or combinations thereof. The devices may comprise or be, for example, transistors, such as MOSFETS, insulated-gate bipolar transistors (IGBTs), or diodes, e.g., Schottky barrier diodes.

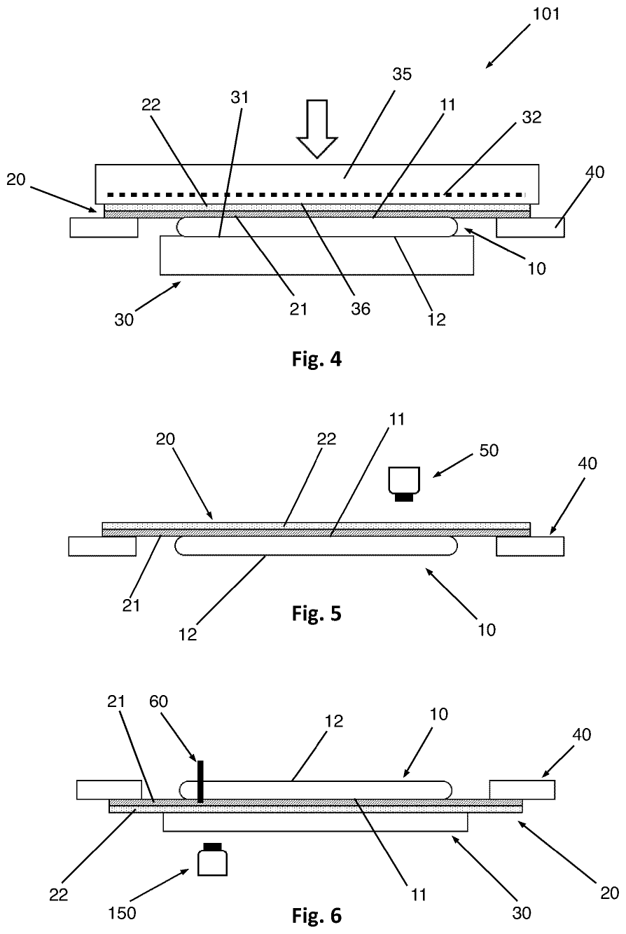

The workpiece 10 may either be supported by the workpiece support 30 on the front side 11 of the workpiece 10 comprising the functional layers or devices (see FIG. 3) or on the back side 12 opposite thereto (see FIG. 4).

The workpiece 10 is not limited to a specific shape. The workpiece 10 may be cylindrical and/or plate-shaped and may comprise cross-sections outlines with (defining a circumferential edge of the workpiece 10) that are substantially round such as oval or circular. In other words, in a top view, the workpiece 10 may generally have a round shape, in particular oval or circular shape.

However, the workpiece 10 may comprise at least one linear section (not illustrated) or notch 13 along the outline of the cross-sections. Particularly in a top view (or a cross-section perpendicular to its longitudinal axis), the workpiece 10 may have a polygonal (plate-) shape, such as a square or rectangular shape. Plate-shaped in the present context means that the workpiece 10 comprises a thickness, i.e., a longitudinal dimension, which is significantly smaller than a transversal/lateral dimension, e.g., a diameter, of the workpiece 10. The circumferential edge of the workpiece 10 may be rounded or chamfered.

The front side 11 and/or the back side 12 of the workpiece 10 is preferably substantially parallel. Moreover, the back side 12 of the workpiece 10 may be substantially flat or even. However, the workpiece 10 has at least on its front side 11 height differences. If a device area 15 is formed on the front side 11 of the workpiece 10, the front side 11 may be formed with a plurality of protrusions, such as bumps protruding from the functional layer. Accordingly, the protrusions result in an uneven front side 11 or surface of the workpiece 10.

Further, the workpiece 10 and in particular the functional layer may also comprise recesses such as grooves. For example, these grooves may be formed in between devices in the form of division lines. Along these division lines, the workpiece 10 is to be divided for obtaining single device chips. Further the functional layer itself formed on the front side 11 may have height differences (with or without bumps).

Accordingly, the front side 11 of the workpiece 10 may have an uneven surface (i.e. a surface structure) due to the presence of multiple devices or device chips.

The following example is used to describe how an uneven surface on the front side 11 of a workpiece 10 is evened out according to the present disclosure by applying a protective sheeting 20. Preferably, the protective sheeting 20 comprises at least a first layer 21 and a second layer 22 or consists thereof. The protective sheeting 20 is configured to adapt to the shape of the workpiece 10 on one side and to provide a flat support surface on the other side opposite to the one side.

The first layer 21 and the second layer 22 may be provided as separate layers to be attached to each other for forming the protective sheeting 20 or may be provided as a prefabricated protective sheeting 20 (e.g., a double-layered film). The protective sheeting may include an adhesive layer for attaching the first layer 21 and the second layer 22 to each other. In contrast to a plate, a film has essentially no bending stiffness when a force is applied perpendicular to the film. The film is preferably formed as a sheeting or may be applied by spray coating.

As illustrated in FIG. 1, the protective sheeting 20 is to be arranged on the first side 11 of the workpiece 10, wherein the first layer 21 is facing the workpiece 10 and the second layer 22 is facing the opposite direction, i.e., away from the workpiece 10.

The first layer 21 of the protective sheeting is configured to be adaptable to the surface structure (i.e., protrusions and/or depressions) present on the front side 11 of the workpiece 10. Protrusions and depressions may be defined on the basis of a mean height (arithmetic) or median height. Alternatively, the peripheral marginal area 16 (where no devices, division lines or streets, chamfered or rounded edges are formed) may have the original height of the bare wafer and may be used as reference height.

In contrast, the second layer 22 is configured to essentially maintain its shape at least or in particular on the side facing away from the workpiece side of the protective sheeting 20 while the first layer 21 adapts its shape as described in more detail below. For reasons discussed below in more detail, the second layer 22 may also be configured for an enhanced heat transfer. With such a configuration the second layer 22 may provide a support surface that is essentially flat and parallel to the second side 12 of the workpiece 10.

These different characteristics of the first layer 21 and the second layer 22 of the protective sheeting 20 allow for providing a uniform support on the side of the second layer 22 (i.e., its exposed side relative to the protective sheeting 20) via a flat surface and to essentially maintain this uniform support at the interface between the first layer 21 and the front side 11 of the workpiece 10.

Preferably, the protective sheeting 20 is applied as a unit when combining a first side 11 of the workpiece 10 and the first layer 21 of the protective sheeting 20. Further, the first layer 21 is made malleable to (at least partly and permanently) adapt its shape whereas the second layer mounted to the first layer is even more preferably essentially not (i.e., it is basically not subject to plastic deformation). It may also be configured for an enhanced absorption of heat.

For the different functions of these layers, the first layer 21 and the second layer 22 are preferably made of a polymer material and are particularly provided as polymer films. Polymer materials have the advantage that they can be manipulated so that they possess the material properties to fulfil the functions of the first layer 21 and the second layer 22 of the protective sheeting 20. As discussed above, the films used preferably have basically no significant bending stiffness. This is particularly advantageous for the first layer 21 that is configured to adapt to the surface structure of the first side 11 of the workpiece 10.

Further, the polymer materials of the first and second layer 21, 22 preferably differ from each other. The first layer 21 is particularly formed of polyolefin and/or polypropylene, whereas the second layer 22 is particularly formed of polyethylene terephthalate (PET).

Preferably, the first layer 21 is at least partly directly attached (i.e., in physical contact) with the front side 11 of the workpiece 10. If a (central) device area 15 is present, the first layer 21 is particularly in contact with the device area 15 and might be in contact with the entire front side 11 (i.e., also the (preferably completely) surrounding peripheral marginal area 16). The extent of the contact may depend on the technique of mounting the first layer 21 to the front side 11.

The first layer 21 is preferably mounted to the entire surface of the front side 11 of the workpiece 10 without an adhesive being interposed between the protective sheeting 20 and the workpiece 10. For example, the mounting may be performed with the steps of combining the first side 11 of the workpiece 10 and the first layer 21 of the protective sheeting 20 and applying heat to the first layer 21 of the protective sheeting 20 through the second layer thereof. In other words, the first layer 21 may be directly mounted to the front side 11 without any adhesive layer in between together with the step of embedding the surface structure of the workpiece's front side 11 in the first layer 21 of the protective sheeting 20.

Thereby, it is prevented that devices or a functional layer formed on the front side 11 of the workpiece 10 is contaminated with an adhesive. Moreover, debonding of the workpiece 10 from the protective sheeting 20 and cleaning of the workpiece 10 (if at all necessary) is facilitated.

Nonetheless and as an alternative, the protective sheeting 20 described above may include an adhesive. In this case, the adhesive is arranged on the side facing the workpiece 10. The adhesive is provided on a circumferential portion of the protective sheeting on 20, in particular an entire circumferential portion of the first layer 21 facing the first side 11 of the workpiece 10. The circumferential portion provided with an adhesive preferably corresponds to a peripheral marginal area 16 surrounding the (central) device area 15 of the workpiece 10.

In embodiments, in which the protective sheeting 20 includes an adhesive arranged on the side facing the workpiece 10, it is preferred that, in a state, in which the front side 11 of the workpiece 10 is arranged on the protective sheeting 20, the adhesive contacts the peripheral marginal area 16 surrounding the device area 15 of the workpiece 10. In other words, it is particularly preferred that the adhesive does not contact the device area 15 of the workpiece 10.

In case of an adhesive arranged in the peripheral marginal area 16 surrounding the device area 15 of the workpiece 10, any height differences that may be caused due to the adhesive or adhesive layer are preferably also compensated by or embedded in the first layer 21.

Further, the first layer 21 and the second layer 22 are preferably mounted to each other without an adhesive layer in between. Nonetheless, an adhesive layer may be used to mount the first and second layers 21, 22 to each other. Accordingly, this adhesive does not get in contact with the first side 11 of the workpiece 10. Using such an adhesive layer facilitates handling of the protective sheeting, particularly when combined with the workpiece 10.

As illustrated in FIGS. 1 to 6, the protective sheeting 20 may include a circumferential excess portion which extends laterally beyond the lateral dimensions of the workpiece 10 for mounting the workpiece 10 to a support frame 40. The support frame 40 is preferably a ring frame (annular frame). The ring frame may surround the workpiece 10.

The support frame 40 is attached to the protective sheeting 20, in to the layer particular first 21. A circumferential portion of the protective sheeting 20 (layer 21) is attached to the support frame 40 such that the protective sheeting 20 closes a central opening of the support frame 40, e.g., the area inside the inner diameter of a ring frame.

As illustrated, the ring frame 40 is preferably attached to the side of the protective sheeting 20 facing the workpiece 10 (i.e., the first layer 21). However, the ring frame 40 may also be provided on the opposite side of the protective sheeting 20.

The step of attaching the ring frame 40 to the protective sheeting 20 may be performed before or during combining the protective sheeting 20 and the workpiece 10. In this way, the handling of the protective sheeting 20, in particular, when arranging the protective sheeting 20 on the workpiece 10, is facilitated.

Further, after arranging the protective sheeting 20 on the workpiece 10, the workpiece 10 can be more easily handled by the support frame 40 via the protective sheeting 20. Thus, handling and transport of the workpiece 10 is facilitated.

Any of the mounting steps described above may be performed under a vacuum environment (i.e., in a vacuum chamber). In particular, the application of the protective sheeting 20 as illustrated in FIG. 1 is preferably performed in a vacuum during and/or after the application or lamination of the protective sheeting 20.

Using vacuum (i.e., a negative pressure) results in the protective sheeting 20 following the height differences (i.e., protrusions or recesses) on the front side 11 of the workpiece 10 in an enhanced manner. As a result, the protective sheeting 20 is more securely attachable since at least less voids and/or air bubbles are present between the protective sheeting 20 and the first side 11 of the workpiece 10. These may otherwise cause the risk of an unintentional separation of the protective sheeting 20 from the workpiece 10. Thus, the attachment of the protective sheeting 20 to the workpiece 10 is enhanced.

A vacuum environment particularly also allows for a secure attachment on the first side 11 of the workpiece 10 particularly in its central region (e.g., corresponding to a device area 15 on the substrate of the workpiece 10) without the use of an adhesive. If no adhesive is used, the protective sheeting 20 (in particular, the first layer 21) can easily and completely be removed from the front side 11 of the workpiece 10 so that essentially no post-processing of the workpiece for removal of residual material might be necessary. In other words, the protective sheeting 20 is not permanent (e.g., it is not part of the singled devices or final products) but is removed after processing the workpiece 10.

For example, the step or steps of arranging the protective sheeting 20 on the first side 11 of the workpiece 10 may be carried out in a vacuum chamber as follows.

After the workpiece 10 and the protective sheeting 20 have been loaded into the vacuum chamber, the chamber is evacuated. Optionally, air may be supplied through an air inlet port to a rubber membrane, causing the rubber membrane to expand into the evacuated chamber and to act as a pressure application means described in more detail further below (see FIGS. 3 and 4). In this way, the rubber membrane is moved towards the workpiece 10 in the vacuum chamber so as to push the protective sheeting 20 against the first side 11 of the workpiece 10.

Alternatively or additionally, a pressing pad 35 may be used to press the protective sheeting 20 and the first side 11 of the workpiece 10 against each other (see FIGS. 3 and 4). Such a pressing pad is essentially rigid in comparison to the protective sheeting 20 in order to obtain a generally flat surface on the side of the second layer 22 that is contact with the pressing pad 35 during application of pressure.

Subsequently, the vacuum in the vacuum chamber is released and the protective sheeting 20 is held in position on the first side 11 of the workpiece 10 by the attachment force generated between the protective sheeting 20 and the workpiece 10. When releasing the vacuum, the atmospheric pressure may also exert a pressing force causing the protective sheeting 20 and the workpiece 10 to be pressed together. This may also support the embedding process into the first layer 21 in relation with the present disclosure.

Further, the vacuum chamber may be used to apply the protective sheeting 20 to the first side 11 of the workpiece 10 via vacuum (e.g., without applying additional pressure using the pressing pad 35 or a membrane). In both cases, the step of heating and applying pressure as described above may be performed after the vacuum has been released or after the workpiece 10 including the protective sheeting have been released from the vacuum chamber (i.e., in addition or alternatively).

Further, the protective sheeting 20 as illustrated in FIGS. 1 to 6 and as described above is preferably applied to the workpiece 10 in a preassembled state (i.e., the layers 21 and 22 have been assembled in advance of performing the present method) or may be assembled as part of the present method. Accordingly, the method may comprise the step of applying a first layer 21 of the protective sheeting 20 with or without an adhesive, which substantially corresponds to a peripheral marginal area 16 surrounding the (central) device area 15 of the workpiece 10, to the front side 11 of the workpiece 10. Then, the second layer 22 of the protective sheeting 20 is applied to the first layer 21, with or without an adhesive layer between the first and the second layer 21, 22. Nonetheless, mounting the second layer 22 to the first layer 21 before applying the assembled protective sheeting 20 to the first side 11 of the workpiece 10 is preferred.

In any case, the application of any of the layers 21, 22 of the protective sheeting 20 is also preferably performed in a vacuum (i.e. using a vacuum chamber). Further, the method may use heat during and/or after any or all of the application or lamination processes described above.

As indicated in FIG. 2, after combining the first side 11 of the workpiece 10 and the first layer 21 of the protective sheeting 20, heat is applied to the first layer 21 of the protective sheeting 20 through the second layer 22 thereof using a heating means 32. Accordingly, the heating means is arranged on the side of the second layer 22 of the protective sheeting. The heating means 32 may be included in a workpiece support 30 (see FIGS. 2 and 3) or in a pressing pad (see FIG. 4).

A heating surface 36 of the heating means 32 is preferably in contact with the second layer 22. Accordingly, the heat is transferred from the heating means 32 into and through the second layer 22 to the first layer 21 of the protective sheeting and preferably reaches the side or surface of the first layer 21 facing the first side 11 of the workpiece 10.

The heat of the heating means 32 transferred to the first layer 21 is controlled to cause the first layer 21 to soften. In particular, the heat is configured to cause the first layer 21 to switch from a solid state to a soft state, in which the first layer may plastically deform or material of the first layer may get displaced from areas of a high compression to areas with a lower compression. A fluid state in the present context means that the material of the first layer 21 of the protective sheeting is able to flow to a degree that a surface structure of the first side 11 of the workpiece 10 may be embedded. In other words, on the first side 11, protrusions are embedded in and recesses are filled by the material of the first layer 21 of the protective sheeting 20.

This embedding process is preferably supported by heating the first layer 21 of the protective sheeting 20 to at least its glass transition temperature but preferably below its melting temperature to avoid tackiness of the first layer (i.e., that the first layer has adhesive properties causing it to stick to the first side 11 of the workpiece 10).

The first layer 21 is particularly heated to a temperature that renders the material soft enough to compensate an unevenness but does not cause the material to develop adhesive properties or adhesive properties to a degree that makes residues stick to the first side 11 upon removal of the protective sheeting 20. Nonetheless, the first layer 21 may be heated beyond the melting temperature of its material if this does not result in such adverse adhesive properties.

For example, if the above-noted materials for the first layer 21 are used (particularly polyolefin or polypropylene), temperatures of at least 60° C. to 160° C., in particular 100° C. to 160° C., are preferred. At this temperature, the first layer 21 becomes sufficiently soft to embed the height differences on the first side 11 of the workpiece 10, whereas the second layer 22 may essentially keep its initial flatness.

In this respect, the heat applied to the first layer 21 via the heating surface 36 preferably results in a temperature of the second layer 22 of the protective sheeting 20 that is below the melting temperature by at least 30° C., 40° C., 50° C., 60° C., or 70° C. and is preferably higher than the glass transition temperature of the material of the first layer 21 of the protective sheeting 20. In this manner, the second layer 22 may maintain a flat support surface more easily.

Nonetheless, it may also be lower than the glass transition temperature by 5° C., 10° C., 15° C., 20° C., or 25° C. Particularly in such a case, the sheet-like shape of the second layer 22 of the protective sheeting 20 may remain essentially unchanged.

Preferably, the second layer 22 or the side of the second layer 22 of the protective sheeting 20 is held on the heating surface 36 of the heating means 32 under suction. Accordingly, the heating surface 36 may at least partly be a porous surface or may have suction grooves to create the negative pressure for holding the protective sheeting 20 under suction.

The heating process is particularly chosen so that the surface structures of the first side 11 of the workpiece 10 (i.e., the volume of the protrusions and/or recesses of a functional layer of the workpiece 10) are embedded by at least 80%, 85%, 90%, 95%, or 98%.

The temperature of the first layer 21 of the protective sheeting is preferably maintained for 15 seconds up to 180 seconds. Although a shorter time is preferred in terms of productivity, it should also be taken into consideration that a longer time allows to reduce stresses acting on the first side 11 of the workpiece 10 during heating (and if this is the case, during application of pressure as discussed further below). A longer time also allows for enhanced embedding and an application of pressure that carries less risk of damaging the workpiece 10.

The heating protocol to perform the heating of the first layer 21 via the second layer 22 of the protective sheeting is preferably a predetermined heating protocol. In other words, the heating process may have been determined in advance using experiments. This is facilitated by the heating process being performed from the side of the protective sheeting 20.

To determine and evaluate the parameters for the heating protocol in these experiments, the extent of embedding as discussed above may be chosen. For example, a possibility to determine whether the embedding is sufficient or not may be by optically inspecting (e.g., using a microscope or camera) the front side 11 of the workpiece 10, in particular from the side of the second layer 22, for air bubbles.

Alternatively or additionally, it may also be possible to use the extent of cracking, fracture, or defect devices (in particular after mechanical processing) as parameters to determine the heating protocol. A predetermined heating protocol has the advantage of a high productivity and less complex production control since no real-time temperature control is necessary (albeit it may still be used).

The heating process is preferably performed under vacuum conditions as described above in relation to mounting the protective sheeting 20.

As illustrated in FIGS. 3 and 4, a pressure application means may be used that applies pressure to enhance embedding of the first side 11 of the workpiece 10 in the first layer 21 of the protective sheeting 20. The application of pressure by the pressure application means is preferably performed at least during and/or after above-described application of heat. Particularly when applying pressure, above noted heating time is preferably more than 30 seconds and even more preferably more than 60 seconds to reduce stress peaks during the embedding process.

In contrast to the application of heat to the side of the second layer 22 of the protective sheeting 20, the pressure application means may apply pressure from either (see FIGS. 3 and 4) or both sides 11, 12 of the workpiece 10.

In FIG. 3, the pressure application means applies pressure from the second side or back side 12 of the workpiece 10 using a pressing pad 35. Accordingly, the heating means 32 is arranged on the side opposite thereto, i.e., the front side 11 of the workpiece 10, where the protective sheeting 20 has been arranged.

In this embodiment, the protective sheeting is arranged on a workpiece support 30 (e.g., a chuck table) that includes heating means 32. As discussed above, the side of the heating means 32 comprising a heating surface 36 (which acts in FIG. 3 also as holding surface 31 of the workpiece support 30) is preferably configured to hold the second layer 22 of the protective sheeting 20 under suction.

In FIG. 4, the pressure application means applies pressure from the first side or front side 11 of the workpiece 10. Thus, the pressure is applied via the protective sheeting 20. Accordingly, the pressure application means and the heating means 32 are both located on the side of the first side 11 of the workpiece 10. In FIG. 4, they are included in a pressing pad 35. In particular due to the heating means 32, the pressing pad 35 may also be configured to hold the protective sheeting 20 under suction. In the exemplary embodiment of FIG. 4, the second side 12 of the workpiece 10 is placed on a holding surface 31 of a workpiece support 30 in the form of a chuck table.

Instead of a pressing pad 35 to apply pressure, above-noted membrane or the like may be used. Preferably, the pressure application means has a rigid flat surface. Such a rigid flat surface is advantageous to achieve an enhanced flat support surface on the side of second layer 22 of the protective sheeting 20, particularly in case of the second layer 22 of the protective sheeting being a film in sheet form.

The attachment of the protective sheeting 20 using heat, particularly in combination with pressure, may result in a form fit of the first layer 21 to the surface structure of the first side 11 of the workpiece 10 (i.e., an interlocking relationship between the first layer 21 and the surface structure of the first side 11 of the workpiece 10). Without wishing to be bound by theory, it is believed that this form fit is achieved by the material of the first layer 21 flowing or deforming around and into the protrusions and recesses of the first side's surface structure, respectively.

As illustrated in FIG. 5, the preparation unit may also include a camera 50 for inspecting the protective sheeting 20 mounted to the first side 11 of the workpiece 10 and/or the first side 11 of the workpiece 10. The camera 50 is arranged on the side of the protective sheeting 20 while the workpiece 10 is supported by a workpiece support (not shown) opposite thereto.

The camera 50 may be used to detect air bubbles (e.g., for determining the degree of embedding by volume or surface). In this configuration, a camera for visible light may be used if the protective sheeting is transmissive for the corresponding wavelengths. Otherwise, an infrared camera may be used for inspecting the first side 11 of the workpiece 10.

Another embodiment that includes a camera 150 is illustrated in FIG. 6. Here, the camera 150 may be used for assisting in inspecting and/or processing the workpiece 10. As schematically shown, the workpiece 10 is supported on a workpiece support 30 on its first side 11, i.e., with the protective sheeting arranged in between. Like in the exemplary embodiment depicted in FIG. 5, the camera 150 may be an infrared camera or a camera for visible light. In the latter case, the workpiece support 30 (e.g., made of a transparent material such as glass) and the protective sheeting 20 are preferably translucent for the wavelengths of visible light.

In general, the materials in between the camera 50, 150 and the object to be observed (in particular the first side 11 of the workpiece 10) should be transmissive for wavelength(s) the camera 50, 150 is able to detect.

In FIG. 6, the camera may be used for inspecting the embedding result as discussed above. It may additionally or alternatively be used to assist in processing the workpiece 10. In FIG. 6, this is schematically illustrated by the dicing blade 60. For example, the camera 150 allows to detect intersecting division lines or streets or cutting position alignment marks formed on the first side 11 of the workpiece 10 to properly position the dicing blade 60 for dividing the workpiece 10 into single device chips. Accordingly, FIG. 6 shows an example of mechanically processing the workpiece 10 with the enhanced support provided by the protective sheeting that has previously been mounted to the first side 11 of the workpiece 10.

In further embodiments, the protective sheeting 20 may also comprise one or more additional layers. Further layers of the protective sheeting 20 may be formed of the same or different material as the layers of the protective sheeting 20. As previously described, a further layer of the protective sheeting 30 may be an adhesive layer.

The protective sheeting 20 may have a thickness in the range of 100 to 500 μm, preferably 100 to 300 μm, and more preferably 150 to 200 μm. In particular, the first layer 21 of the protective sheeting 20 has a thickness that is higher than the difference between the highest and deepest point of a surface structure located on the first side 11 of the workpiece 10.

### Reference signs

1, 101 preparation unit
10 workpiece
11 first side or front side
12 second side or back side
13 notch
14 street
15 device area
16 peripheral marginal area
20 protective sheeting
21 first layer
22 second layer
30 workpiece support (e.g. chuck table)
31 holding surface
32 heating means
35 pressing pad
36 heating surface
40 support frame
50, 150 camera
60 dicing blade

1. A method of preparing a workpiece for processing, comprising:
providing the workpiece;
providing a protective sheeting comprising at least a first layer and a second layer, wherein the second layer is formed of a material having a higher glass-transition temperature or melting temperature than the first layer;
combining a first side of the workpiece and the first layer of the protective sheeting; and
applying heat to the first layer of the protective sheeting through the second layer thereof.

2. The method according to claim 1, wherein
when applying heat to the first layer of the protective sheeting, the first side of the workpiece is facing a heating means, and the first layer of the protective sheeting is preferably in contact with the first side of the workpiece.

3. The method according to claim 2, further comprising:
arranging the second layer of the protective sheeting on the heating means, wherein the heating means is configured to apply heat to the first layer of the protective sheeting through the second layer thereof,
wherein the second layer is preferably in contact with the heating means.

4. The method according to claim 3,
wherein the second layer of the protective sheeting is held on the heating means-under suction.

5. The method according to claim 1
wherein the first layer and the second layer are formed of a polymer material, and
wherein the polymer materials of the first and second layer are different.

6. The method according to claim 5,
wherein the first layer is formed of polyolefin or polypropylene, and/or
wherein the second layer is formed of polyethylene terephthalate.

7. The method according to claim 1,
wherein surface structures are formed on the first side of the workpiece, and
wherein, when applying heat to the first layer of the protective sheeting, the first layer is softened, such that the surface structures are embedded in the first layer, and
wherein, when applying heat to the protective sheeting, preferably only the first layer is softened.

8. The method according to claim 1,
wherein the first layer of the protective sheeting is heated to a temperature above the glass-transition temperature or melting temperature of the first layer but below the glass-transition temperature or melting temperature of the second layer.

9. The method according to claim 1
wherein the step of arranging a first side of the workpiece on the first layer of the protective sheeting and/or applying heat to the first layer of the protective sheeting is essentially performed under vacuum condition, preferably inside a vacuum chamber.

10. The method according to claim 1,
wherein, while or after applying heat to the first layer of the protective sheeting through the second layer thereof, the workpiece and the protective sheeting are pressed against each other, preferably by applying a pressure load via the workpiece and/or the second layer of the protective sheeting.

11. The method according to claim 1,
wherein the second layer, in particular the side of the second layer opposite to the side facing the first layer, comprises a substantially flat shape, and
wherein, when applying heat to the first layer of the protective sheeting, the shape of the second layer remains essentially unchanged.

12. A preparation unit for preparing a workpiece, the preparation unit being configured for attaching a protective sheeting to the workpiece, the protective sheeting comprising at least a first layer to be arranged on the workpiece side and a second layer to be arranged on the side opposite to the workpiece side, the workpiece preparation unit comprising:
a workpiece support including a holding surface for holding the workpiece via the second layer
a heating means; and
a control unit configured to control the heating means so that the first layer is heated via the second layer according to a predetermined heating protocol.

13. The preparation unit according to claim 12, further comprising a pressure application means arranged for applying a pressure load to the first layer.

14. The preparation unit according to claim 12, further comprising a camera arranged for inspecting an exposed surface of the second layer of the protective sheeting attached to the workpiece.
